(19) United States
(12) Patent Application Publication
(10) Pub. No.: US 2008/0224257 A1
(43) Pub. Date: Sep. 18, 2008

(54) Semiconductor device

(75) Inventor: Yasuhiro Mori, Nukata-gun (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 12/073,818

(22) Filed: Mar. 11, 2008

(30) Foreign Application Priority Data
Mar. 12, 2007 (JP) 2007-61736
Jan. 16, 2008 (JP) 2008-006946

(51) Int. Cl. H01L 23/34; H01L 27/12; H05K 7/20

(52) U.S. Cl. 257/507; 361/709; 257/618; 257/E23.08; 257/E27.112

(57) ABSTRACT

A semiconductor device includes a silicon-on-insulator substrate having a supporting substrate, an electrically insulating layer on the supporting substrate, and a semiconductor layer on the insulating layer. The semiconductor layer includes element regions for providing semiconductor elements and an isolation region located around the element region and extending to the insulating layer. The element regions are electrically isolated from each other by the isolation region. The semiconductor device further includes a thermal conductor disposed in the isolation region of the semiconductor layer and extending from a front side to a back side of the silicon-on-insulator substrate by penetrating through the insulating layer and the supporting substrate.

### CROSS REFERENCE TO RELATED APPLICATION

This application is based on and incorporates herein by reference Japanese Patent Applications No. 2007-61736 filed on Mar. 12, 2007 and No. 2008-6946 filed on Jan. 16, 2008.

### FIELD OF THE INVENTION

The present invention relates to a semiconductor device having a structure for efficiently dissipating heat generated therein.

### BACKGROUND OF THE INVENTION

A semiconductor device has been proposed that uses a semiconductor substrate having a silicon-on-insulator structure, in which element regions, where semiconductor elements are formed, are electrically isolated from each other, for example, by trench isolation. When a power semiconductor element, which generates a relatively large amount of heat during operation, is formed in the element region, it is preferable that the semiconductor device should have heat dissipation structure.

JP-A-2000-243826 discloses a semiconductor device having a heat dissipation structure. In the semiconductor device, a conductor is placed in a trench for isolation and elongated to an electrode pad, which is connected to a lead frame by a bonding wire. Heat generated in the semiconductor device travels through the conductor and the bonding wire and is dissipated at the lead frame serving as a heatsink. However, the semiconductor device has the following disadvantages. Since the heat dissipation path from the semiconductor device to the lead frame is long, heat dissipation efficiency is low. Further, the lead frame needs to have a ground terminal for heat dissipation. Furthermore, since the semiconductor device needs to have a bonding bad for heat dissipation, layout design flexibility of the semiconductor device is reduced.

### SUMMARY OF THE INVENTION

In view of the above-described problem, it is an object of the present invention to provide a semiconductor device having a simple structure for efficiently dissipating heat generated therein.

According to an aspect of the present invention, a semiconductor device includes a silicon-on-insulator substrate and a thermal conductor having a thermal conductivity. The silicon-on-insulator substrate includes a supporting substrate, an electrically insulating layer on the supporting substrate, and a semiconductor layer on the insulating layer. The semiconductor layer includes an element region for providing a semiconductor element and an isolation region located around the element region and extending to the insulating layer. The thermal conductor is disposed in the isolation region of the semiconductor layer and extends from a front side to a back side of the silicon-on-insulator substrate by penetrating through the insulating layer and the supporting substrate. Heat generated by the semiconductor element formed in the element region of the semiconductor layer is dissipated outside the silicon-on-insulator substrate by traveling through the thermal conductor.

According to another aspect of the present invention, a semiconductor device includes a semiconductor substrate and a thermal conductor having a thermal conductivity. The semiconductor substrate includes an electrically insulating layer on and a semiconductor layer on the insulating layer. The semiconductor layer includes an element region for providing a semiconductor element and an isolation region located around the element region and extending to the insulating layer. The thermal conductor is disposed in the isolation region of the semiconductor layer and extends from a front side to a back side of the semiconductor substrate by penetrating through the insulating layer. Heat generated by the semiconductor element formed in the element region of the semiconductor layer is dissipated outside the semiconductor substrate by traveling through the thermal conductor.

According to further another aspect of the present invention, a semiconductor device includes a silicon-on-insulator substrate and a thermal conductor having a thermal conductivity. The silicon-on-insulator substrate includes a supporting substrate, an electrically insulating layer on the supporting substrate, and a semiconductor layer on the insulating layer. The semiconductor layer includes an element region for providing a semiconductor element and an isolation region located around the element region and extending to the insulating layer. The thermal conductor is disposed on an outer perimeter of the isolation region of the semiconductor layer and extends from a front side to a back side of the silicon-on-insulator substrate by penetrating through the insulating layer and the supporting substrate. Heat generated by the semiconductor element formed in the element region of the semiconductor layer is dissipated outside the silicon-on-insulator substrate by traveling through the thermal conductor.

### BRIEF DESCRIPTION OF THE DRAWINGS

The above and other objectives, features and advantages of the present invention will become more apparent from the following detailed description made with check to the accompanying drawings. In the drawings:

FIG. 1 is a diagram illustrating a cross-sectional view of a semiconductor device according to a first embodiment of the present invention;

FIG. 2 is a diagram illustrating a top view of the semiconductor device of FIG. 1;

FIGS. 3A-3D are diagrams illustrating processes of manufacturing the semiconductor device of FIG. 1;

FIG. 4A is a diagram illustrating a top view of a semiconductor device according to a first modification of the semiconductor device of FIG. 1, FIG. 4B is a diagram illustrating a top view of a semiconductor device according to a second modification of the semiconductor device of FIG. 1, and FIG. 4C is a diagram illustrating a top view of a semiconductor device according to a third modification of the semiconductor device of FIG. 1;

FIG. 5 is a diagram illustrating a cross-sectional view of a semiconductor device according to a second embodiment of the present invention;

FIG. 6 is a diagram illustrating a cross-sectional view of a semiconductor device according to a third embodiment of the present invention;

FIG. 7 is a diagram illustrating a cross-sectional view of a semiconductor device according to a fourth embodiment of the present invention;

FIG. 8 is a diagram illustrating a top view of the semiconductor device of FIG. 7;

FIG. 9A is a diagram illustrating a top view of a semiconductor device according to a first modification of the semiconductor device of FIG. 7, FIG. 9B is a diagram illustrating a top view of a semiconductor device according to a second modification of the semiconductor device of FIG. 7, and FIG. 9C is a diagram illustrating a top view of a semiconductor device according to a third modification of the semiconductor device of FIG. 7;

FIG. 10 is a diagram illustrating a cross-sectional view of a semiconductor device according to a fifth embodiment of the present invention;

FIG. 11 is a diagram illustrating a cross-sectional view of a semiconductor device according to a sixth embodiment of the present invention;

FIG. 12 is a diagram illustrating a top view of the semiconductor device of FIG. 11;

FIG. 13A is a diagram illustrating a top view of a semiconductor device according to a first modification of the semiconductor device of FIG. 11, FIG. 13B is a diagram illustrating a top view of a semiconductor device according to a second modification of the semiconductor device of FIG. 11, and FIG. 13C is a diagram illustrating a top view of a semiconductor device according to a third modification of the semiconductor device of FIG. 11;

FIG. 14 is a diagram illustrating a cross-sectional view of a semiconductor device according to a seventh embodiment of the present invention; and

FIG. 15 is a diagram illustrating a cross-sectional view of a semiconductor device according to an eighth embodiment of the present invention.

### DETAILED DESCRIPTION OF THE PREFERRED EMBODIMENTS

### First Embodiment

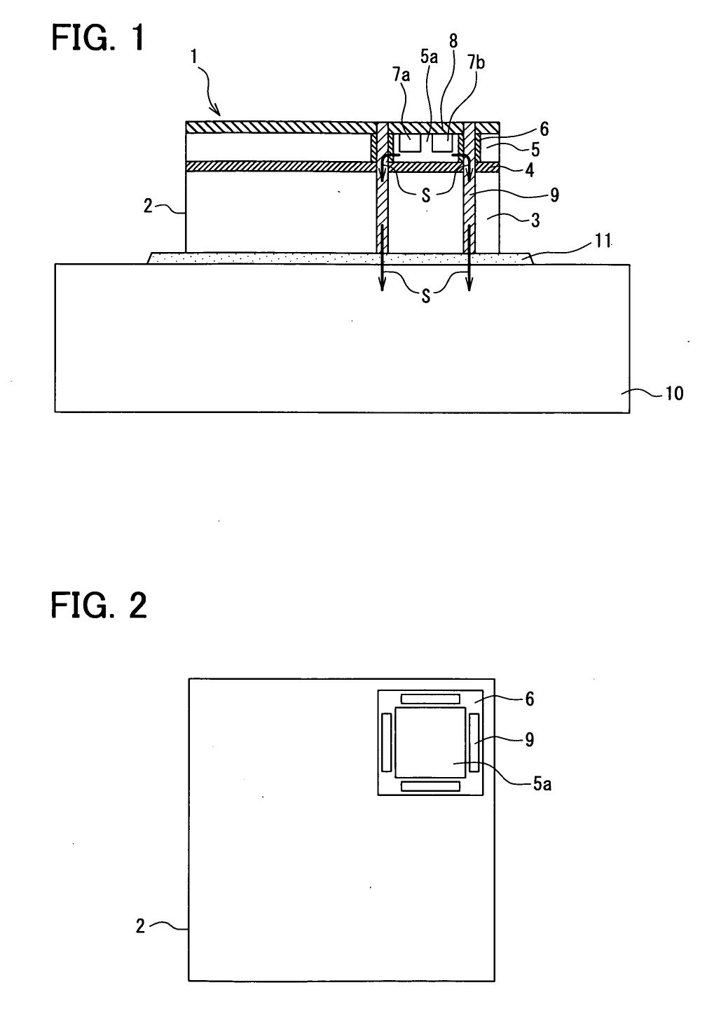

Referring to FIGS. 1, 2, a semiconductor chip 1 according to a first embodiment of the present invention is constructed by using a silicon-on-insulator (SOI) substrate 2. An integrated circuit having power semiconductor elements such as bipolar transistors, metal-oxide semiconductor field-effect transistors (MOSFET), insulated gate bipolar transistors (IGBT) is fabricated on the front side of the semiconductor chip 1. The SOI substrate 2 includes a silicon substrate 3 serving as a supporting substrate, a silicon oxide layer 4 serving as an electrically insulating layer, and a semiconductor layer 5 made of monocrystalline silicon. The silicon oxide layer 4 is disposed on top of the silicon substrate 3, and the semiconductor layer 5 is disposed on top of the silicon oxide layer 4. Thus, the semiconductor layer 5 is located on the front side of the SOI substrate 2, the silicon substrate 3 is located on the back side of the SOI substrate 2, and the silicon oxide layer 4 is located between the semiconductor layer 5 and the silicon substrate 3.

The semiconductor layer 5 is divided into a plurality of element regions 5a by an isolation region 6. The isolation region 6 is formed by forming a trench extending from a surface of the semiconductor layer 5 to the silicon oxide layer 4 and by filling the trench with an electrically insulating material such as silicon oxide. Thus, each element region 5a is enclosed by the silicon oxide layer 4 and the isolation region 6 so that the element regions 5a are totally, electrically isolated from each other.

For example, as shown in FIG. 2, the isolation region 6 forms a hollow rectangle to enclose the element region 5a therein, when viewed from the front side of the SOI substrate 2. A thermal conductor 9 is disposed in each side of the rectangle isolation region 6. The thermal conductor 9 is located at a middle portion rather than end portions of the side of the rectangular isolation region 6. In other words, the thermal conductor 9 is not located at corner portions of the rectangular isolation region 6. A width of the thermal conductor 9 is less than a width of the side of the hollow rectangle so that the thermal conductor 9 is positioned within the isolation region 6 and covered with the silicon oxide. The thermal conductor 9 extends from the front side to a back side of the SOI substrate 2 by penetrating through the silicon oxide layer 4 and the silicon substrate 3. The thermal conductor 9 is exposed to at least the back side of the SOI substrate 2. The thermal conductor 9 has both electrical conductivity and high thermal conductivity substantially equal to thermal conductivity of metal.

Diffusion regions 7a, 7b are formed in the element region 5a, for example, by a photolithography process for patterning, an impurity implantation process, and the like. A power semiconductor element such as a bipolar transistor, a field-effect transistor (FET), diode, or a resistor is formed in the element region 5a by using the diffusion regions 7a, 7b.

After the semiconductor element is formed in the element region 5a, an interlayer dielectric film (not shown) is disposed on top of the semiconductor layer 5, and a wiring trace (not shown) is formed on the interlayer dielectric film. As shown in FIG. 1, the semiconductor chip 1 is mounted and fixed on a die pad 10 of a lead frame (not shown) through an electrically conductive adhesive 11 such as silver paste. The die pad 10 may be, for example, made of copper.

As indicated by a directional arrow S of FIG. 1, heat generated by the semiconductor element formed in the element region 5a travels through the thermal conductor 9 and is dissipated at the die pad 10. Thus, the semiconductor chip 1 can achieve high heat dissipation efficiency.

According to the semiconductor chip 1 of the first embodiment, since heat dissipation path from the semiconductor chip 1 to the die pad 10 is short, the heat can be efficiently dissipated from the semiconductor chip 1. Further, the semiconductor element formed in the element region 5a can be protected from noise, because the element region 5a is surrounded by the thermal conductor 9, which can serve as an electromagnetic shield.

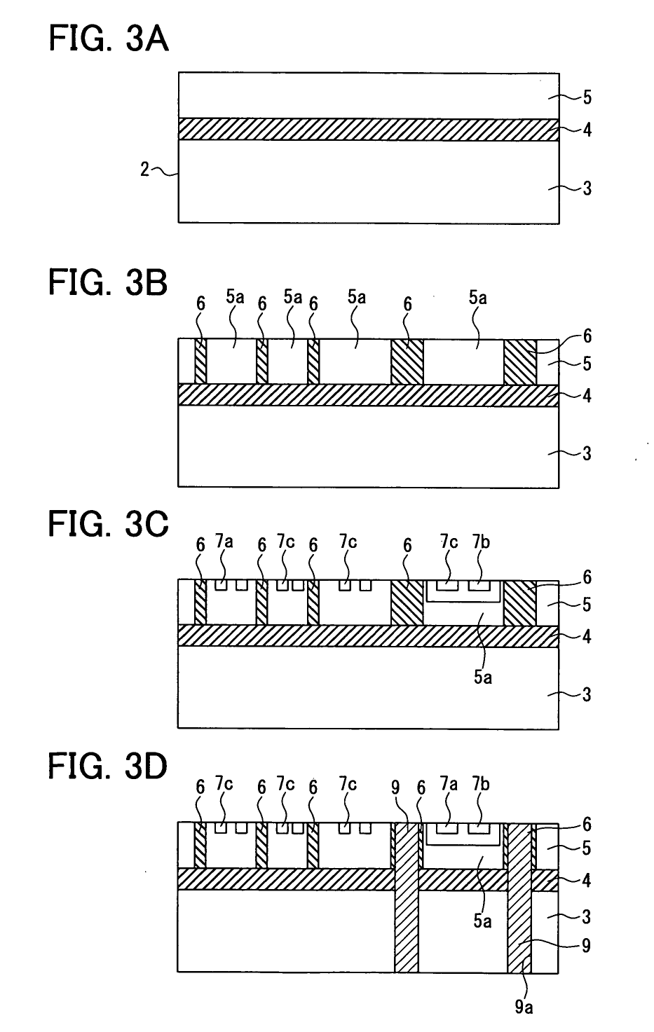

A process of manufacturing the semiconductor chip 1 is described below with reference with FIGS. 3A-3D.

In FIG. 3A, the SOI substrate 2 is prepared. Specifically, the silicon oxide layer 4 is formed on the silicon substrate 3. One side of another silicon substrate for the semiconductor layer 5 is polished to a mirror finish and then bonded on the silicon oxide layer 4. The other side of the other silicon substrate is polished so that the other silicon substrate can have a thickness necessary for the semiconductor layer 5.

In FIG. 3B, the trench is formed to the SOI substrate 2 to divide the semiconductor layer 5 into the element regions 5a. The trench is formed by vertically etching the semiconductor layer 5 to the silicon oxide layer 4 in a dry etching process such as a reactive ion etching (RIE) process by using a patterned mask, which is formed by patterning a photoresist in a photolithography process. Then, the isolation region 6 is formed by filling the trench with the silicon oxide, for example, in a chemical vapor deposition (CVD) process and by planarizing the trench filled with the silicon oxide. Thus, the element regions 5a are electrically isolated from each other by the isolation region 6.

In FIG. 3C, the semiconductor element such as a transistor, a, diode, a capacitor, or a resister is formed in each element region 5a. Specifically, diffusion regions 7a, 7b, 7c are formed by implanting impurities to the element regions 5a by using a patterned mask, which is formed by patterning a photoresist in a photolithography process. Then, the interlayer dielectric film (not shown) is formed on the semiconductor layer 5, and the wiring trace (not shown) is formed on the interlayer dielectric film. Thus, the semiconductor elements formed in the element regions 5a are electrically connected to each other by the wiring trace and construct an integrated circuit. Then, the silicon substrate 3 is polished to a predetermined thickness, for example, substantially equal to the thickness of the semiconductor layer 5. For example, the silicon substrate 3 is polished to a thickness of 10 micrometers (μm).

In FIG. 3D, a through hole 9a is formed in the isolation region 6 to extend from the front side to the back side of the SOI substrate 2 by penetrating through the silicon oxide layer 4 and the silicon substrate 3. Then, the thermal conductor 9 is formed by filling the through hole 9a with a conductive material, for example, in a CVD process. The through hole 9a can be formed, for example, in a RIE process.

The through hole 9a is formed surrounded by the silicon oxide in the isolation region 6. In other words, the isolation region 6 defines the through hole 9a, and sidewalls of the through hole 9a are formed of the silicon oxide. Therefore, the thermal conductor 9 is electrically isolated from the element region 5a. The thermal conductor 9 may be, for example, made of copper, aluminum, tungsten, or the like. Alternatively, the polishing of the silicon substrate 3 to the predetermined thickness can be performed after the thermal conductor 9 is formed.

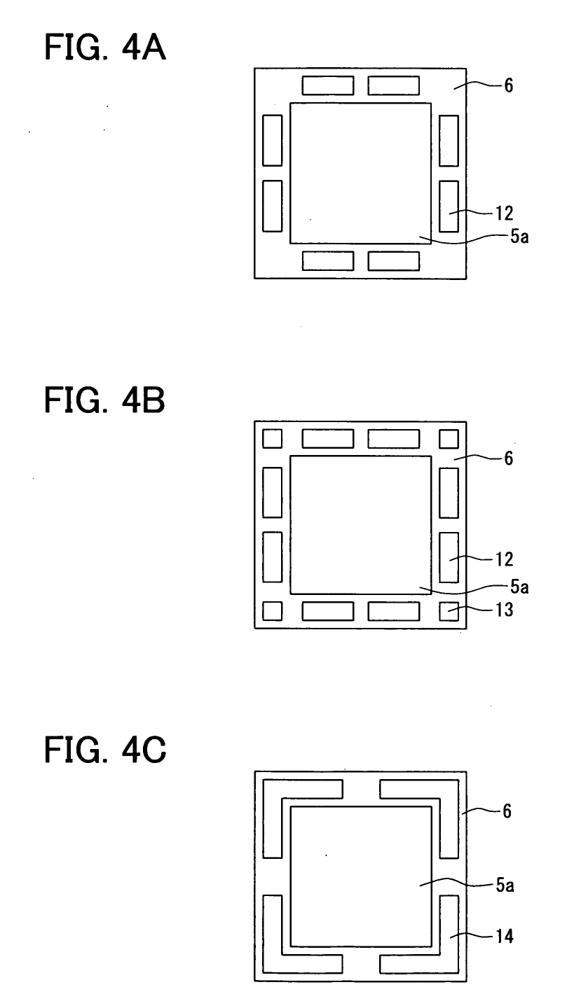

Modifications of the first embodiment are described below with reference to FIGS. 4A-4C. In the first embodiment, as shown in FIG. 2, one conductor 9 is disposed in each side of the isolation region 6.

According to a first modification shown in FIG. 4A, two conductors 12 are disposed in each side of the isolation region 6. In such an approach, contact area between the isolation region 6 and the thermal conductor 9 increases, and strength of the semiconductor chip 1 is improved. According to a second modification shown in FIG. 4B, in addition to the thermal conductors 12, a thermal conductor 13 is disposed in each corner of the isolation region 6 to improve heat dissipation efficiency. According to a third modification shown in FIG. 4C, a L-shaped conductor 14 is disposed in each corner of the isolation region 6.

### Second Embodiment

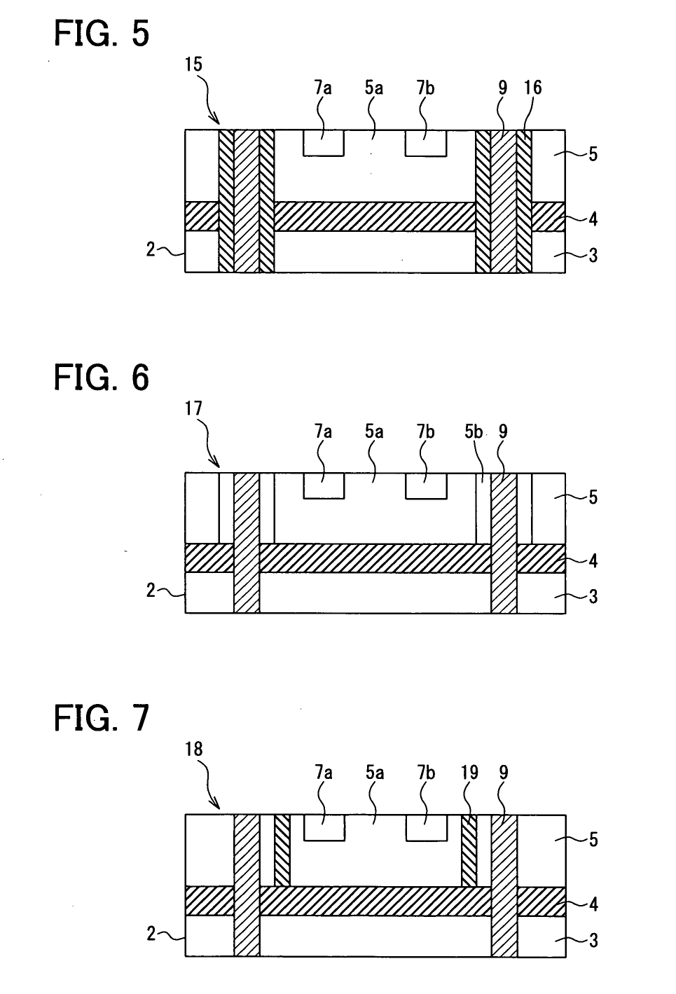

A semiconductor chip 15 according to a second embodiment of the present invention is described below with reference to FIG. 5. A difference between the semiconductor chips 1, 15 is as follows. In the semiconductor chip 1 shown in FIG. 1, the isolation region 6 is formed only in the semiconductor layer 5 of the SOI substrate 2. In the semiconductor chip 15 shown in FIG. 5, an isolation region 16 is formed to extend from the front side to the back side of the SOI substrate 2 by penetrating through the semiconductor layer 5, the silicon oxide layer 4, and the silicon substrate 3. Thus, the isolation region 16 is exposed to the back side of the SOI substrate 2. The thermal conductor 9 extends from the front side to the back side of the SOI substrate 2 within the isolation region 16. Therefore, the thermal conductor 9 is totally covered with (i.e., surrounded by) the silicon oxide, with which the isolation region 16 is filled. In such an approach, the thermal conductor 9 is totally electrically isolated so that a leak current can be prevented from flowing through the thermal conductor 9.

### Third Embodiment

A semiconductor chip 17 according to a third embodiment of the present invention is described below with reference to FIG. 6. A difference between the semiconductor chips 1, 17 is as follows. In the semiconductor chip 1 shown in FIG. 1, the element regions 5a are electrically isolated from each other by the isolation region 6, which is formed by filling the trench with the silicon oxide. Thus, the semiconductor chip 1 employs trench isolation. In the semiconductor chip 17 shown in FIG. 6, the element regions 5a are electrically isolated from each other by a diffusion region 5b having a conductivity type opposite to a conductive type of the element region 5a. For example, the conductivity type of the element region 5a is a p-type, and the conductivity type of the diffusion region 5b is an n-type. Thus, the semiconductor chip 17 employs p-n junction isolation. The diffusion region 5b extends from the surface of the semiconductor layer 5 to the silicon oxide layer 4.

According to the semiconductor chip 17 of the third embodiment, the element region 5a and the diffusion region 5b construct a p-n junction. The element regions 5a can be electrically isolated from each other by reverse biasing the p-n junction. The p-n junction isolation simplifies a manufacturing process of the semiconductor chip 17 by removing a process of forming a trench filled with silicon oxide, which is necessary for the trench isolation. Accordingly, the semiconductor chip 17 can be manufactured at lower cost.

### Fourth Embodiment

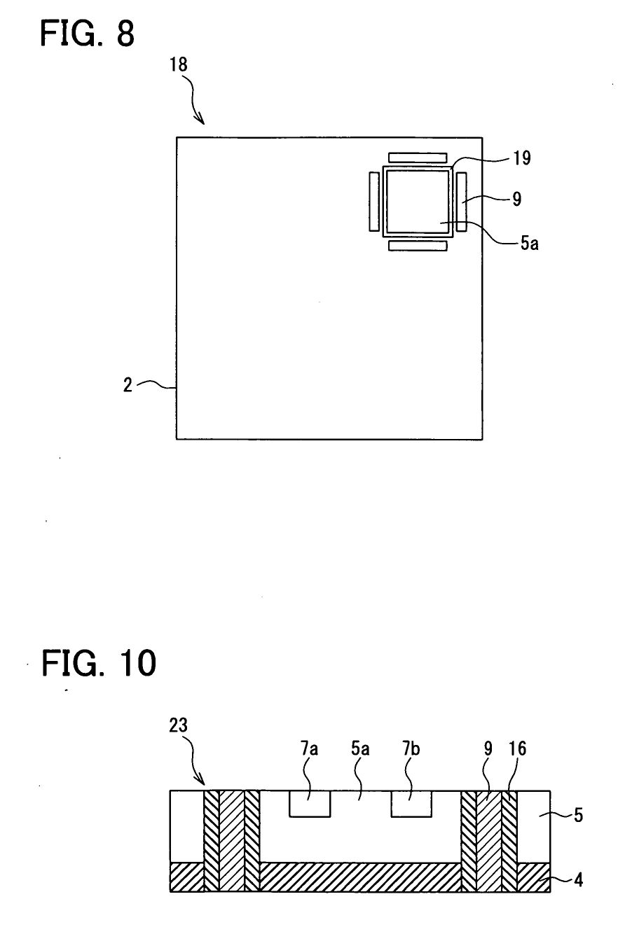

A semiconductor chip 18 according to a fourth embodiment of the present invention is described below with reference to FIGS. 7 and 8. A difference between the semiconductor chips 1, 18 is as follows. In the semiconductor chip 1, as shown in FIG. 2, the thermal conductor 9 is disposed within the isolation region 6. In the semiconductor chip 17, as shown in FIG. 8, the thermal conductor 9 is disposed outside of an isolation region 19. When viewed from the front side of the SOI substrate2, the isolation region 19 forms a hollow rectangle to enclose the element region 5a therein. The thermal conductor 9 is located along each side of the rectangular isolation region 19. In other words, the thermal conductor 9 is not located at corner portions of the rectangular isolation region 6. In such an approach, like the semiconductor chip 1, the semiconductor chip 18 can achieve high heat dissipation efficiency.

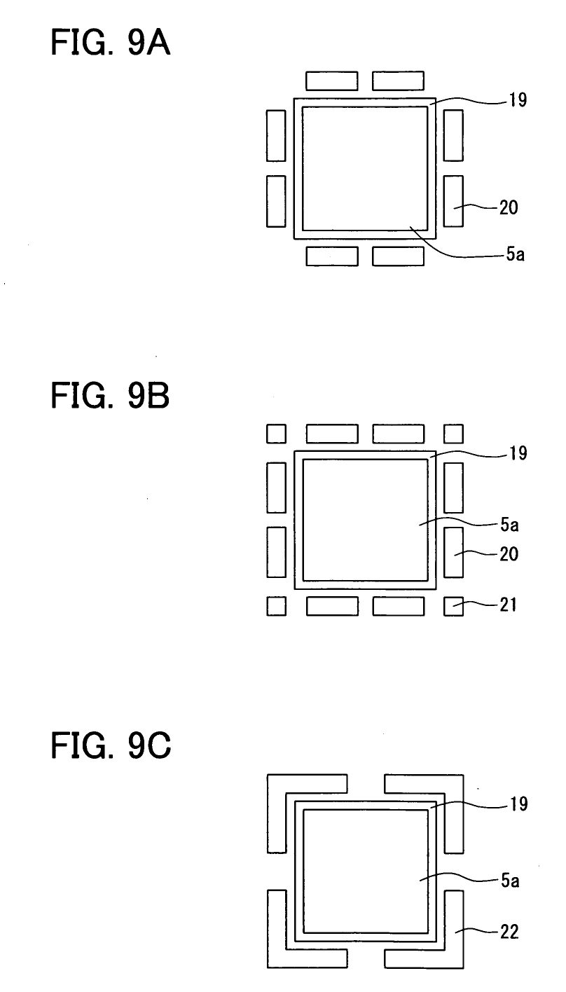

Modifications of the fourth embodiment are described below with reference to FIGS. 9A-9C. According to a first modification shown in FIG. 9A, two conductors 20 are disposed at each side of the isolation region 19. According to a second modification shown in FIG. 9B, in addition to the thermal conductors 20, a thermal conductor 21 is disposed at each corner of the isolation region 19 to improve heat dissipation efficiency. According to a third modification shown in FIG. 9C, a L-shaped conductor 14 is disposed at each corner of the isolation region 19.

### Fifth Embodiment

A semiconductor chip 23 according to a fifth embodiment of the present invention is described below with reference to FIG. 10. A difference between the semiconductor chips 15, 23 is as follows. The semiconductor chip 15 shown in FIG. 5 has the silicon substrate 3, which serves as a supporting substrate. The semiconductor chip 23 shown in FIG. 10 has no supporting substrate. In such an approach, the length of the thermal conductor 9 is shortened so that the heat generated from the element region 5a can be efficiently transferred to the die pad 10 through the thermal conductor 9. In the semiconductor chip 23, the isolation region 16 extends to a bottom surface of the silicon oxide layer 4 by penetrating through the silicon oxide layer 4. Alternatively, like the semiconductor chip 1 shown in FIG. 1, the isolation region 16 can extend to reach a top surface of the silicon oxide layer 4.

### Sixth Embodiment

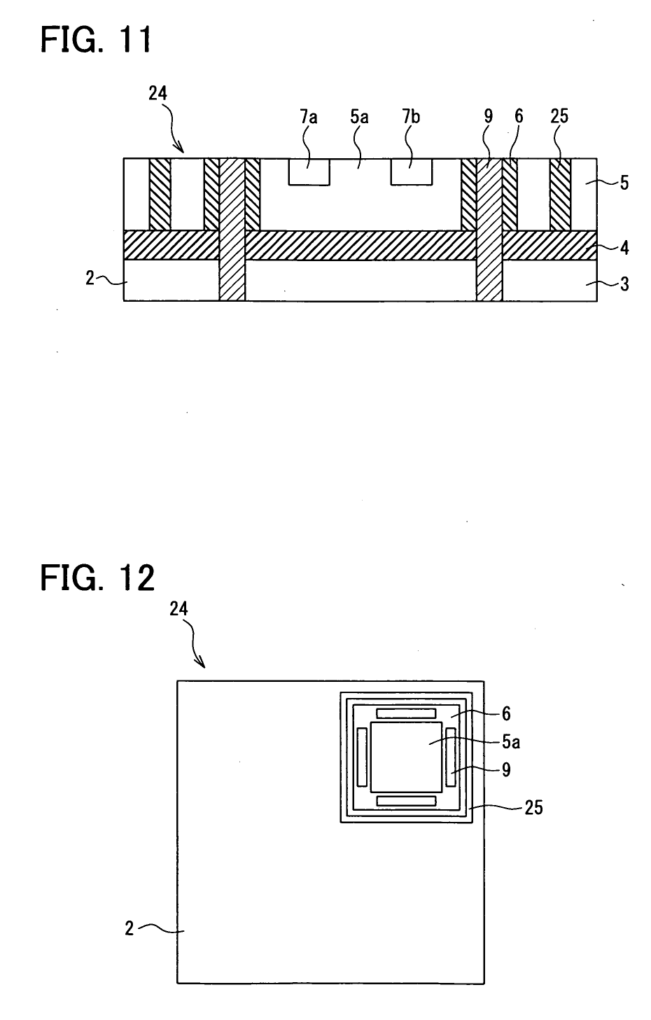

A semiconductor chip 24 according to a sixth embodiment of the present invention is described below with reference to FIGS. 11 and 12. A difference between the semiconductor chips 1, 24 is as follows. The semiconductor chip 24 further includes additional outer isolation region 25 for enclosing the inner isolation region 6, which encloses the element region 5a. Thus, the element region 5a is doubly enclosed by isolation regions 6, 25 to improve electrical isolation. In FIGS. 11 and 12, the thermal conductor 9 is disposed in the inner isolation region 6. Alternatively, the thermal conductor 9 can be disposed in the outer isolation region 25.

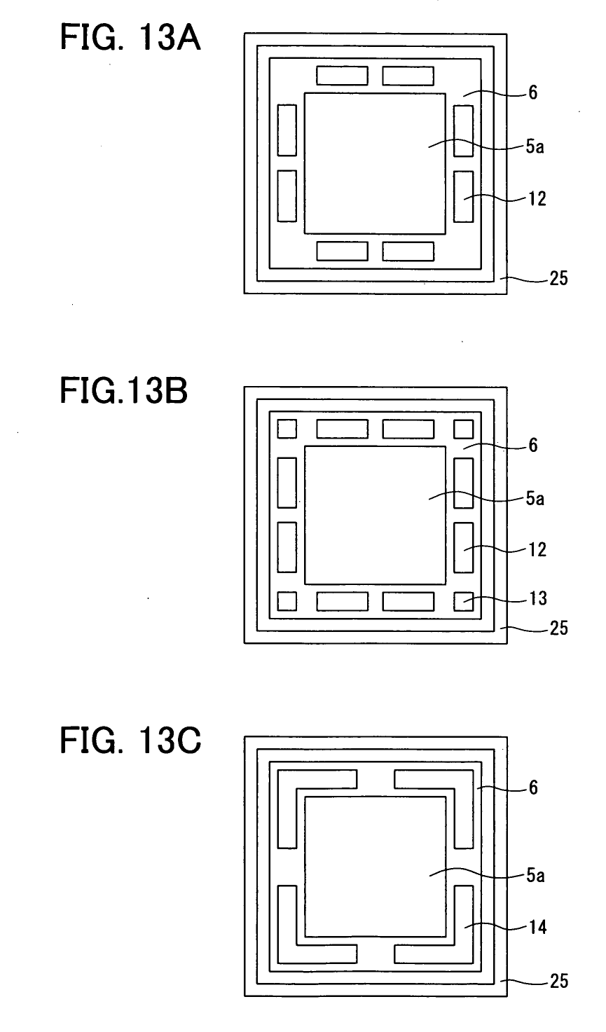

Modifications of the sixth embodiment are described below with reference to FIGS. 13A-13C. According to a first modification shown in FIG. 13A, two conductors 12 are disposed in each side of the inner isolation region 6. According to a second modification shown in FIG. 13B, in addition to the thermal conductors 12, the thermal conductor 13 is disposed in each corner of the inner isolation region 6 to improve heat dissipation efficiency. According to a third modification shown in FIG. 13C, the L-shaped conductor 14 is disposed in each corner of the inner isolation region 6.

### Seventh Embodiment

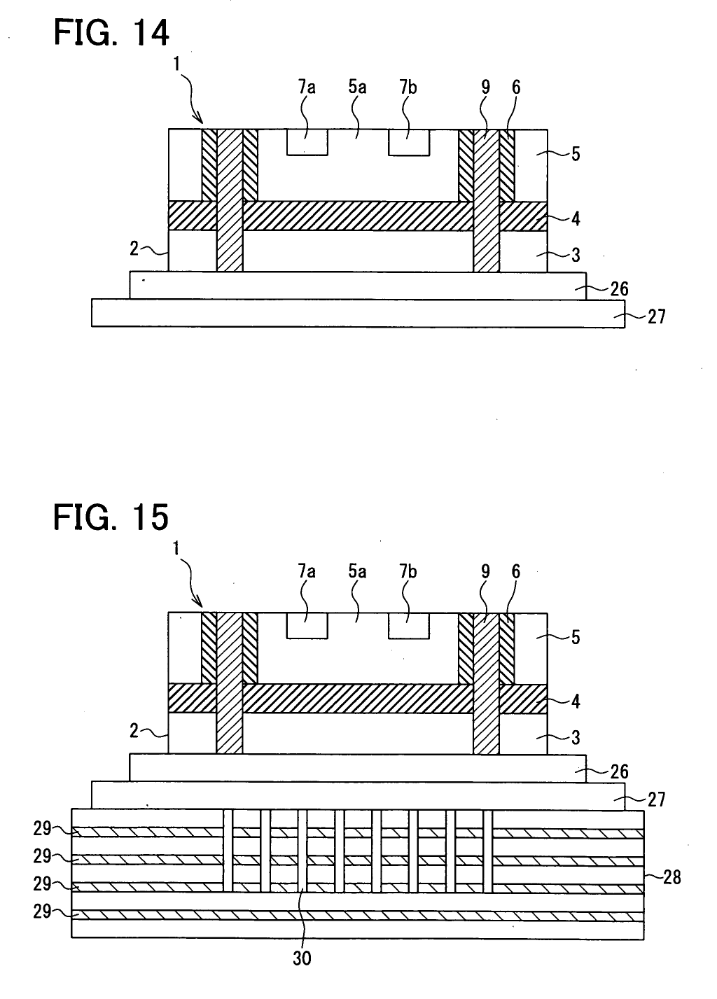

A seventh embodiment of the present invention is described below with reference to FIG. 14. In the seventh embodiment, the semiconductor chip 1 of the first embodiment is mounted and fixed on a die pad 26, and the die pad 26 is thermally coupled to a heatsink 27. In such an approach, the heat dissipation efficiency of the semiconductor chip 1 can be improved.

### Eighth Embodiment

An eighth embodiment of the present invention is described below with reference to FIG. 15. In the eighth embodiment, the semiconductor chip 1 of the seventh embodiment is mounted on a printed circuit board 28. The printed circuit board 28 includes conductor layers 29 for multilayer wiring. The printed circuit board 28 further includes thermal vias 30 that extend in a thickness direction of the printed circuit board 28 to contact at least one of the conductor layers 29. The heat generated by the semiconductor chip 1 is transferred to the heatsink 27 and then transferred to the conductor layers 29 through the thermal vias 30 of the printed circuit board 28. Thus, the heat generated by the semiconductor chip 1 can be dissipated through both the heatsink 27 and the printed circuit board 28. In such an approach, the heat dissipation efficiency of the semiconductor chip 1 can be more improved.

The semiconductor chip 1 is positioned corresponding to the thermal vias 30 of the printed circuit board 28 to increase heat dissipation efficiency. For example, as shown in FIG. 15, the semiconductor chip 1 can be positioned above the thermal vias 30 so that the heat can be efficiently dissipated through the printed circuit board 28.

(Modifications)

The embodiments described above may be modified in various ways. For example, the thermal conductor 9 can be made of a material other than metal, as long as the material has both thermal conductivity and electrical conductivity. The shape, length, and thickness of the thermal conductor 9 can be adjusted according to need. The thermal conductor 9 can be disposed in a region other than the isolation region 6 around the element region 5a where a power semiconductor element is formed. To allow the thermal conductor 9 to penetrate through the silicon substrate 3, the thermal conductor 9 can be partially formed in the silicon substrate 3, and then the silicon substrate 3 can be polished until the thermal conductor 9 is exposed.

Such changes and modifications are to be understood as being within the scope of the present invention as defined by the appended claims.

What is claimed is:

1. A semiconductor device comprising:
a silicon-on-insulator substrate having a front side and a back side opposite to the front side, the silicon-on-insulator substrate including a supporting substrate, an electrically insulating layer on the supporting substrate, and a semiconductor layer on the insulating layer, the semiconductor layer including an element region for providing a semiconductor element and an isolation region located around the element region and extending to the insulating layer, and
a thermal conductor having a thermal conductivity and disposed in the isolation region of the semiconductor layer, the thermal conductor being extending from the front side to the back side of the silicon-on-insulator substrate by penetrating through the insulating layer and the supporting substrate.

2. The semiconductor device according to claim 1,
wherein the isolation region is a trench filled with an electrically insulating material.

3. The semiconductor device according to claim 2,
wherein the isolation region extends to the back side of the silicon-on-insulator substrate by penetrating through the insulating layer and the supporting substrate.

4. The semiconductor device according to claim 1,
wherein the semiconductor layer has a first conductivity type, and
wherein the isolation region of the semiconductor layer is an impurity diffusion region having a second conductive type opposite to the first conductivity type.

5. The semiconductor device according to claim 1,
wherein the semiconductor element generates heat.

6. The semiconductor device according to claim 1,
wherein the element region is enclosed by the isolation region.

7. The semiconductor device according to claim 6,
wherein the isolation region has a hollow polygonal shape having a plurality of sides, and
wherein the thermal conductor is disposed in at least one of the plurality of sides.

8. The semiconductor device according to claim 1, further comprising:
a die pad,
wherein the silicon-on-insulator substrate is mounted on the die pad through a conductive adhesive.

9. The semiconductor device according to claim 8, further comprising:
a heatsink,
wherein the die pad is mounted on the heatsink.

10. The semiconductor device according to claim 9, further comprising:
a printed circuit board having a thermal via,
wherein the heatsink is mounted on the printed circuit board, and
wherein the silicon-on-insulator substrate is positioned corresponding to the thermal via of the printed circuit board.

11. A semiconductor device comprising:
a semiconductor substrate having a front side and a back side opposite to the front side, the semiconductor substrate including an electrically insulating layer and a semiconductor layer on the insulating layer, the semiconductor layer including an element region for providing a semiconductor element and an isolation region located around the element region and extending to the insulating layer, and
a thermal conductor having a thermal conductivity and disposed in the isolation region of the semiconductor layer, the thermal conductor being extending from the front side to the back side of the semiconductor substrate by penetrating through the insulating layer.

12. The semiconductor device according to claim 11,
wherein the isolation region is a trench filled with an electrically insulating material.

13. The semiconductor device according to claim 11,
wherein the semiconductor layer has a first conductivity type, and
wherein the isolation region of the semiconductor layer is an impurity diffusion region having a second conductive type opposite to the first conductivity type.

14. A semiconductor device comprising:
a silicon-on-insulator substrate having a front side and a back side opposite to the front side, the silicon-on-insulator substrate including a supporting substrate, an electrically insulating layer on the supporting substrate, and a semiconductor layer on the insulating layer, the semiconductor layer including an element region for providing a semiconductor element and an isolation region located around the element region and extending to the insulating layer, and
a thermal conductor having a thermal conductivity and disposed on an outer perimeter of the isolation region of the semiconductor layer, the thermal conductor being extending from the front side to the back side of the silicon-on-insulator substrate by penetrating through the insulating layer and the supporting substrate.

15. The semiconductor device according to claim 14,
wherein the isolation region is a trench filled with an electrically insulating material.

16. The semiconductor device according to claim 15,
wherein the isolation region extends to the back side of the silicon-on-insulator substrate by penetrating through the insulating layer and the supporting substrate.

17. The semiconductor device according to claim 14,
wherein the semiconductor layer has a first conductivity type, and
wherein the isolation region of the semiconductor layer is an impurity diffusion region having a second conductive type opposite to the first conductivity type.
